(19) United States
(12) Patent Application Publication
(10) Pub. No.: US 2020/0018804 A1
(43) Pub. Date: Jan. 16, 2020

(54) ELECTRIC CURRENT SENSOR

(71) Applicant: Hitachi Metals, Ltd., Tokyo (JP)

(72) Inventors: Ken OKUYAMA, Tokyo (JP); Naoki FUTAKUCHI, Tokyo (JP); Yujiro TOMITA, Tokyo (JP)

(21) Appl. No.: 16/457,099

(22) Filed: Jun. 28, 2019

(30) Foreign Application Priority Data
Jul. 13, 2018 (JP) 2018-133599

(51) Int. Cl. G01R 33/09; G01R 15/20; G01R 19/00

(52) U.S. Cl. CPC G01R 33/098; G01R 19/0092; G01R 15/205

(57) ABSTRACT

An electric current sensor includes a plate-like shape bus bar, through which an electric current to be detected is to be passed, one pair of shield plates, which are made of a magnetic material and disposed in such a manner as to sandwich the bus bar between the one pair of the shield plates in a thickness direction of the bus bar, a magnetic detection element, which is disposed between the bus bar and one of the shield plates to detect a strength of a magnetic field to be produced by the electric current to be passed through the bus bar, a core, which is made of a magnetic material and disposed between the one pair of the shield plates, and a winding, which includes one part wound around the core, and an other part wound around either of the shield plates.

### CROSS-REFERENCE TO RELATED APPLICATION

The present invention is based on Japanese Patent Application No. 2018-133599 filed on Jul. 13, 2018, the entire contents of which are incorporated herein by reference.

### BACKGROUND OF THE INVENTION

### 1. Field of the Invention

The present invention relates to an electric current sensor.

### 2. Description of the Related Art

Conventionally, there is known an electric current sensor, which includes a magnetic detection element to detect the strength of a magnetic field to be produced by an electric current to be detected (see, e.g., JP-A-2016-164523). By detecting the strength of the magnetic field with the magnetic detection element, it is possible to compute the electric current, based on the strength of the magnetic field.

[Patent Document 1] JP-A-2016-164523

### SUMMARY OF THE INVENTION

In the electric current sensor using the magnetic detection element, minimizing the influence of a disturbance generating external magnetic field is desired. To this end, covering the magnetic detection element with a shield can be considered, but even in this case, the influence of a disturbance caused when a high frequency AC (alternating current) magnetic field is applied as the disturbance (the disturbance generating external magnetic field) may be unable to be sufficiently suppressed.

Accordingly, it is an object of the present invention to provide an electric current sensor, which is substantially unaffected even by a disturbance generated by an externally applied high frequency AC (alternating current) magnetic field.

For the purpose of solving the above-described problem, the present invention provides an electric current sensor, comprising:

a plate-like shape bus bar, through which an electric current to be detected is to be passed;

one pair of shield plates, which are made of a magnetic material and disposed in such a manner as to sandwich the bus bar between the one pair of the shield plates in a thickness direction of the bus bar;

a magnetic detection element, which is disposed between the bus bar and one of the shield plates to detect a strength of a magnetic field to be produced by the electric current to be passed through the bus bar;

a core, which is made of a magnetic material and disposed between the one pair of the shield plates; and

a winding, which includes one part wound around the core, and an other part wound around either of the shield plates.

### POINTS OF THE INVENTION

According to the present invention, it is possible to provide the electric current sensor, which is substantially unaffected even by a disturbance generated by an externally applied high frequency AC magnetic field.

### BRIEF DESCRIPTION OF THE DRAWINGS

FIG. 1A is a perspective view showing an electric current sensor according to one embodiment of the present invention;

FIG. 1B is a cross-sectional view taken along line A-A of FIG. 1A;

FIGS. 2A and 2B are perspective views showing a shield plate, a core and a winding;

FIG. 3 is an explanatory diagram for explaining a principle to suppress a disturbance in the electric current sensor;

FIG. 4A is a magnetic field vector diagram showing a simulation result on a conventional example;

FIG. 4B is a graph diagram showing the relationships between the detected magnetic flux proportion and the frequency for each phase of a disturbance generating external magnetic field in the conventional example;

FIG. 5A is a magnetic field vector diagram showing a simulation result on a comparative example;

FIG. 5B is a graph diagram showing the relationships between the detected magnetic flux proportion and the frequency for each phase of a disturbance generating external magnetic field in the comparative example;

FIG. 6A is a magnetic field vector diagram showing a simulation result on an invention example;

FIG. 6B is a graph diagram showing the relationships between the detected magnetic flux proportion and the frequency for each phase of a disturbance generating external magnetic field in the invention example;

FIG. 7 is a graph diagram showing together maximal values of the detected magnetic flux proportions at each frequency in FIGS. 4B, 5B, and 6B; and

FIG. 8 is a cross-sectional view of an electric current sensor according to one modification to the present invention.

### DETAILED DESCRIPTION OF THE PREFERRED EMBODIMENTS

### Embodiment

An embodiment of the present invention will be described below in conjunction with the attached drawings.

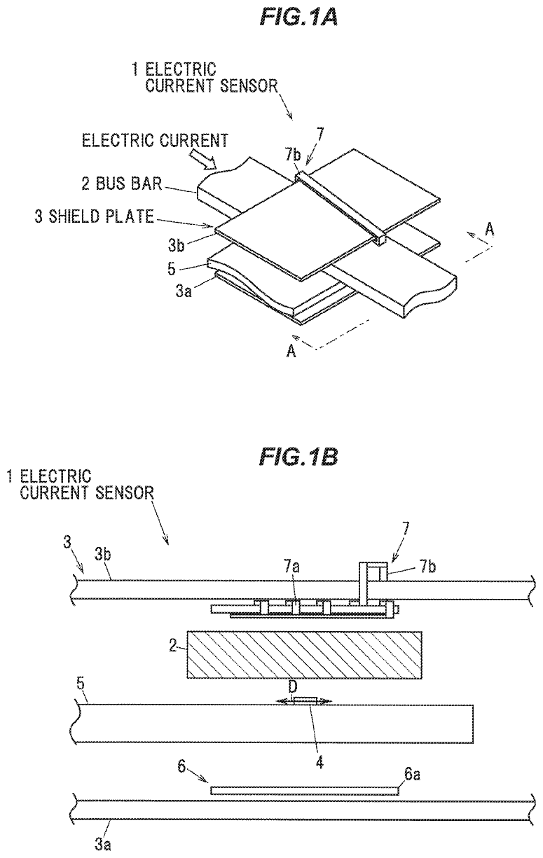

FIG. 1A is a perspective view showing an electric current sensor 1 according to the present embodiment, and FIG. 1B is a cross-sectional view taken along line A-A of FIG. 1A.

As shown in FIGS. 1A and 1B, the electric current sensor 1 is configured to include a plate-like shape bus bar 2 through which an electric current to be detected is to be passed, one pair of shield plates 3, which are made of a magnetic material and disposed in such a manner as to sandwich the bus bar 2 between the one pair of shield plates 3 in a thickness direction of the bus bar 2, and a magnetic detection element 4, which is disposed between the bus bar 2 and one of the shield plates 3 to detect a strength of a magnetic field to be produced by the electric current to be passed through the bus bar 2.

The bus bar 2 is configured as a plate-like shape conductor made of a good electric conductor such as copper, aluminum or the like, and being designed to serve as an electric current path through which an electric current is to be passed. The bus bar 2 is designed to be used as a power supply line between a motor and an inverter in an electric vehicle or a hybrid vehicle, for example. The bus bar 2 has a thickness of e.g. 3 mm. In the present embodiment, the electric current is passed in a length direction of the bus bar 2.

The magnetic detection element 4 is configured to detect a magnetic field strength (magnetic flux density) in a direction along a detection axis D, and output an output voltage signal according to the detected magnetic field strength (magnetic flux density). As the magnetic detection element 4, a Hall element, a Giant Magneto Resistive effect (GMR) element, an AMR (Anisotropic Magneto Resistive) element, a TMR (Tunneling Magneto Resistive) element, or the like can be used, for example. The magnetic detection element 4 is arranged to be oriented opposite the bus bar 2 in the thickness direction of the bus bar 2. The magnetic detection element 4 is arranged in such a manner that its detection axis D is oriented in a width direction (in a direction perpendicular to the length direction and to the thickness direction) of the bus bar 2.

The shield plates 3 are configured to intercept an external magnetic field (a disturbance). The shield plates 3 are arranged in such a manner as to sandwich the bus bar 2 and the magnetic detection element 4 between those shield plates 3 in the thickness direction of the bus bar 2. Further, the shield plates 3 are arranged in such a manner that their surfaces are located parallel to surfaces of the bus bar 2 (the thickness direction of the shield plates 3 and the thickness direction of the bus bar 2 are the same), with the shield plates 3 being spaced apart from the bus bar 2. A conductive or nonconductive ferromagnetic material can be used as the shield plates 3. Herein, the shield plates 3 made of a silicon steel plate having a thickness of 1.0 mm are used. Hereinafter, the magnetic detection element 4 side shield plate 3 will be referred to as the first shield plate 3a, while the bus bar 2 side shield plate 3 will be referred to as the second shield plate 3b.

Hereinafter, in FIG. 1A, the vertical direction will be referred to as the thickness direction, and the left rear to the right front direction will be referred to as the length direction, while the left front to the right rear direction will be referred to as the width direction. The shield plates 3 are formed in a rectangular plate-like shape having two opposite sides in the width direction and two opposite sides in the length direction.

The magnetic detection element 4 is arranged to be located midway between both the shield plates 3a and 3b in the thickness direction. This is because locating the magnetic detection element 4 midway (or adjacent to the midway) between both the shield plates 3a and 3b makes it possible to reduce the hysteresis effect in the relationship between the electric current and the magnetic flux density to be detected in the magnetic detection element 4, and thereby enhance the electric current detection accuracy. The magnetic detection element 4 is mounted on a substrate 5. The substrate 5 is arranged between the bus bar 2 and the first shield plate 3a, with its surface mounted with the magnetic detection element 4 being oriented to the bus bar 2.

A mold resin not shown is arranged to fill the space between the shield plates 3a and 3b, in such a manner that the shield plates 3a and 3b, the magnetic detection element 4 and the bus bar 2 are integrally configured with the mold resin. The mold resin acts to both hold the locational relationships between the magnetic detection element 4, the bus bar 2, and both the shield plates 3 constant to suppress the occurrence of a detection error due to vibration and the like, and suppress the occurrence of a detection error due to ingress of a foreign object into the space between the shield plates 3a and 3b.

(Configuration to Suppress a Disturbance Caused by a High Frequency)

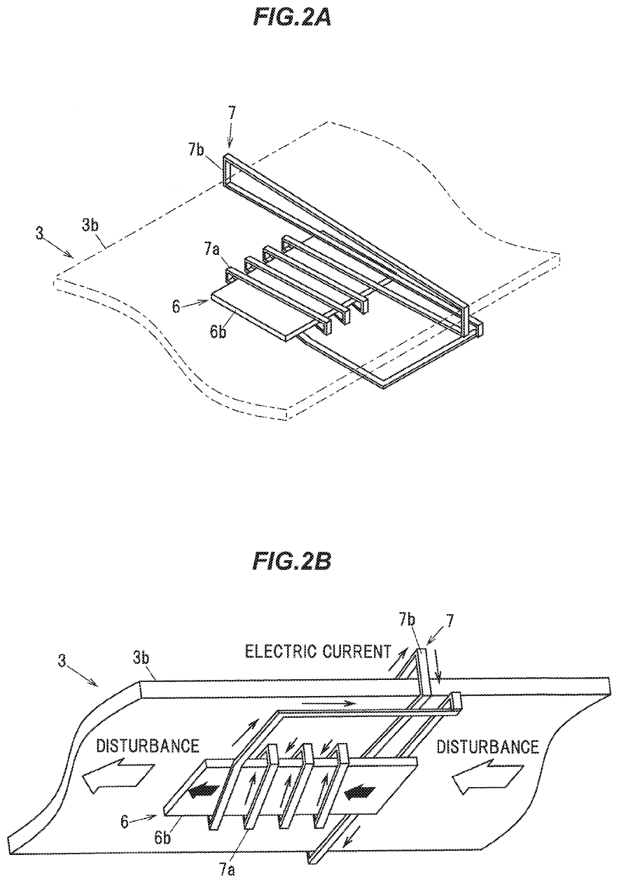

FIGS. 2A and 2B are perspective views showing the shield plate 3 (the second shield plate 3b), a core and a winding. As shown in FIGS. 1A, 1B, 2A and FIG. 2B, the electric current sensor 1 is configured to further include a core 6, which is made of a magnetic material and disposed between the one pair of shield plates 3, and a winding 7, which includes one part of the winding 7 being wound around the core 6 and an other part of the winding 7 being wound around the shield plate 3 (the second shield plate 3b).

The core 6 is configured as a plate-like shape member made of a ferromagnetic material, and herein, the core 6 made of a silicon steel plate having a thickness of 0.5 mm thick is used. The core 6 is formed in a rectangular plate-like shape having two opposite sides in the width direction and two opposite sides in the length direction, as with the shield plates 3. The core 6 is formed in such a manner that its length and width are smaller than the lengths and widths of the shield plates 3, and the core 6 is arranged in such a manner that the entire core 6 is sandwiched between the one pair of shield plates 3. That is, the entire core 6 is covered in the shield plates 3 in a plan view when viewed in the thickness direction. This results in difficulty in external magnetic field inputting to the core 6.

Note that it is also possible to use the core 6 formed in a columnar shape such as a circular columnar shape, for example. It should be noted, however, that, in the present embodiment, the plate-shaped core 6 is used because the arrangement space for the core 6 is limited in such a manner that the spacing between the shield plates 3 is as narrow as on the order of 10 mm, for example.

In the present embodiment, one pair of the cores 6 are arranged both between the magnetic detection element 4 and one shield plate 3 (the first shield plate 3a), and between the magnetic detection element 4 and the other shield plate 3 (the second shield plate 3b), respectively. The one pair of cores 6 are arranged in such a manner as to sandwich the magnetic detection element 4 and the bus bar 2 between the one pair of cores 6 in the thickness direction. Further, the cores 6 are arranged to be spaced apart from the shield plates 3 respectively, and are provided in non-contact with the shield plates 3 respectively. The one pair of shield plates 3 are arranged in such a manner as to sandwich the one pair of cores 6, the magnetic detection element 4, and the bus bar 2 together between the one pair of shield plates 3 in the thickness direction. Hereinafter, the first shield plate 3a side core 6 will be referred to as the first core 6a, while the second shield plate 3b side core 6 will be referred to as the second core 6b. The first core 6a is arranged between the substrate 5 and the first shield plate 3a. The second core 6b is arranged between the second shield plates 3b and the bus bar 2.

The winding 7 is configured as a linear shape conductor covered with an insulator, and is made of a magnet wire such as an enameled wire or the like, for example. Although in the present embodiment, a rectangular wire having a substantially rectangular shape conductor cross section is used as the winding 7, the winding 7 is not limited thereto, but a wire having a substantially circular shape conductor cross section may be used as the winding 7.

In the present embodiment, one part of the winding 7 is wound around the second core 6b, while the other part of the winding 7 is wound around the second shield plate 3b. Further, no winding 7 is wound around the first core 6a and the first shield plate 3a. This is because simulation results, which will be described later, showed that a sufficient disturbance suppressing effect was able to be obtained by only winding the winding 7 around one of the cores 6 and one of the shield plates 3 (the second core 6b and the second shield plate 3b). Hereinafter, the one part of the winding 7 being wound around the second core 6b will be referred to as the core wound part 7a of the winding 7, while the other part of the winding 7 being wound around the second shield plate 3b will be referred to as the shield plate wound part 7b of the winding 7.

Although in the present embodiment the winding 7 is wound around only the second core 6b and the second shield plate 3b, the winding 7 may be wound around only the first core 6a and the first shield plate 3a. Further, when no sufficient disturbance suppressing effect can be obtained with only one of the cores 6 and one of the shield plates 3, the windings 7 may be wound both around the first core 6a and the first shield plate 3a, and around the second core 6b and the second shield plate 3b, respectively.

Note that it is possible to omit the core 6 provided with no winding 7, but that, in this case, the breakdown of the symmetry of the cores 6 with respect to the central magnetic detection element 4 in the thickness direction may increase the hysteresis effect (the hysteresis effect in the relationship between the electric current and the magnetic flux density to be detected in the magnetic detection element 4). By using the one pair of cores 6, it is possible to arrange the cores 6 made of the magnetic material symmetrically with respect to the central magnetic detection element 4 in the thickness direction, and thereby reduce the hysteresis effect.

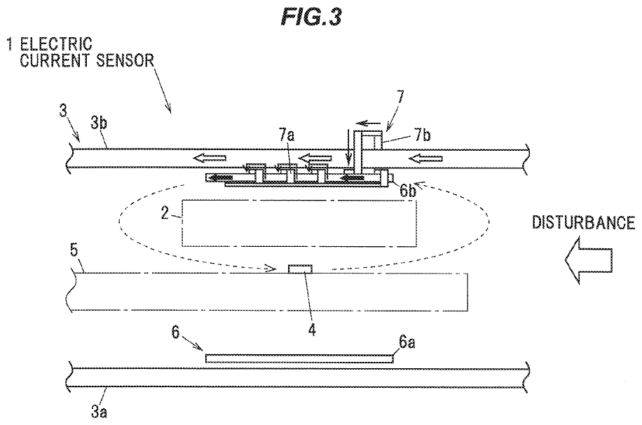

Herein, using FIG. 2B and FIG. 3, a principle to suppress a disturbance generated in the electric current sensor 1 by an external magnetic field will be described. Assuming that a disturbance generating external magnetic field is produced in a horizontal direction in FIG. 3, a magnetic flux (as indicated by outline arrows) resulting from a disturbance being generated by the external magnetic field is passing through the second shield plate 3b made of the magnetic material, and through the shield plate wound part 7b of the winding 7. Herein, an AC magnetic field is applied as the disturbance (the disturbance generating external magnetic field), resulting in the magnetic field through the shield plate wound part 7b of the winding 7 temporally changing, generating an induction current (as indicated by solid line arrows) in the shield plate wound part 7b of the winding 7.

The induction current generated in the shield plate wound part 7b of the winding 7 flows into the core wound part 7a of the winding 7, and the induction current flowing in the core wound part 7a creates an induction magnetic field (as indicated by black filled arrows) in the second core 6b. Herein, the direction of the induction magnetic field being created in the second core 6b is the same as the direction of the disturbance generating external magnetic field. The induction magnetic field being created in the second core 6b forms such a closed loop (as indicated by broken line arrows) that, in the location of the magnetic detection element 4, the induction magnetic field is created in the opposite direction to the direction of the disturbance generating external magnetic field, thereby suppressing the influence of the disturbance being generated by the external magnetic field. By adding the cores 6 and the winding 7 in this manner, a passive disturbance suppressing mechanism is achieved, that responds to the disturbance generating AC magnetic field to create the induction magnetic field in such a direction as to cancel out the disturbance generated by the AC magnetic field.

Since the magnetic detection element 4 detects only a magnetic field in a direction along the detection axis D, the location and orientation of the second core 6b (the distance of the second core 6b from the magnetic detection element 4 and the axial direction of the core wound part 7a of the winding 7) may appropriately be determined in such a manner as to be able to cancel out a disturbance generating external magnetic field in a direction along the detection axis D. More specifically, the second core 6b may be arranged in such a manner that an induction magnetic field to be created therein by an induction current flowing in the core wound part 7a includes a direction component along the detection axis D of the magnetic detection element 4.

Note that when the induction magnetic field to be created in the second core 6b by the induction current flowing in the core wound part 7a has no direction component along the detection axis D of the magnetic detection element 4, for example by guiding the induced magnetic flux with a magnetic path forming member such as a yoke and the like, it is possible to create the induction magnetic field in a direction along the detection axis D in the location of the magnetic detection element 4. It should be noted, however, that, in this case, since the magnetic path forming member such as a yoke and the like is required leading to an increase in the number of parts, it is desirable to arrange the second core 6b in such a manner that the induction magnetic field includes a direction component along the detection axis D, unless there is some special reason.

Further, a number of turns in the core wound part 7a of the winding 7 may be larger than a number of turns in the shield plate wound part 7b of the winding 7. This makes it possible to amplify the disturbance generating external magnetic field passing through the second shield plate 3b, and thereby create the high induction magnetic field in the second core 6b side, allowing an enhancement in the disturbance suppressing effect. In addition, the magnetic field induced in the second core 6b due to the influence of the electric current flowing in the bus bar 2 and the like is not likely to be transmitted to the second shield plate 3b side. The specific number of turns in the core wound part 7a of the winding 7 and the specific number of turns in the shield plate wound part 7b of the winding 7 may appropriately be determined according to the magnitude and the like of the expected disturbance generating external magnetic field, in view of use conditions and the like.

(Simulation)

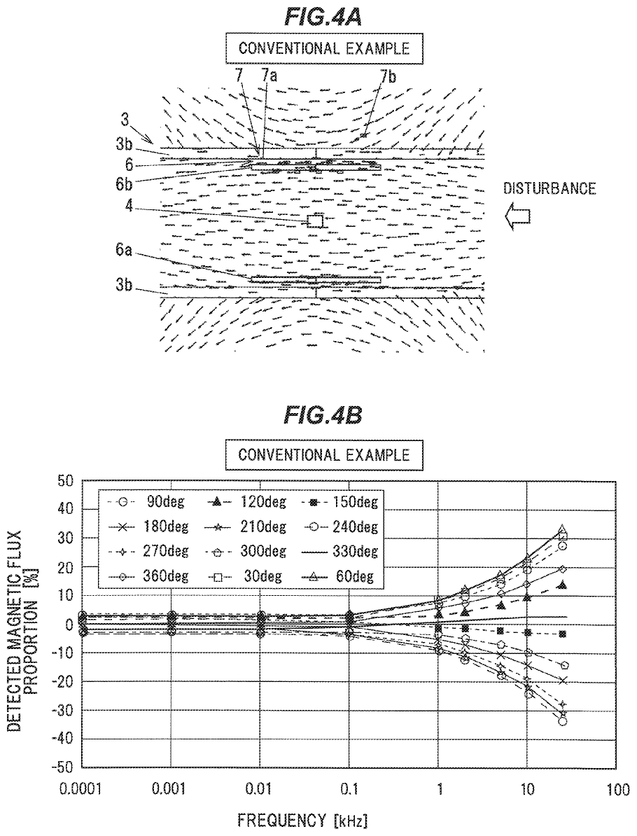

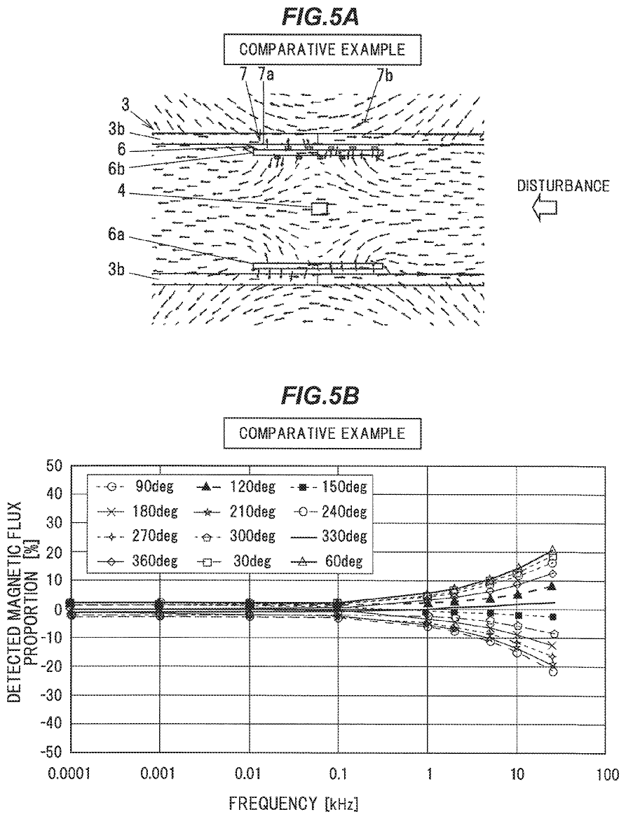

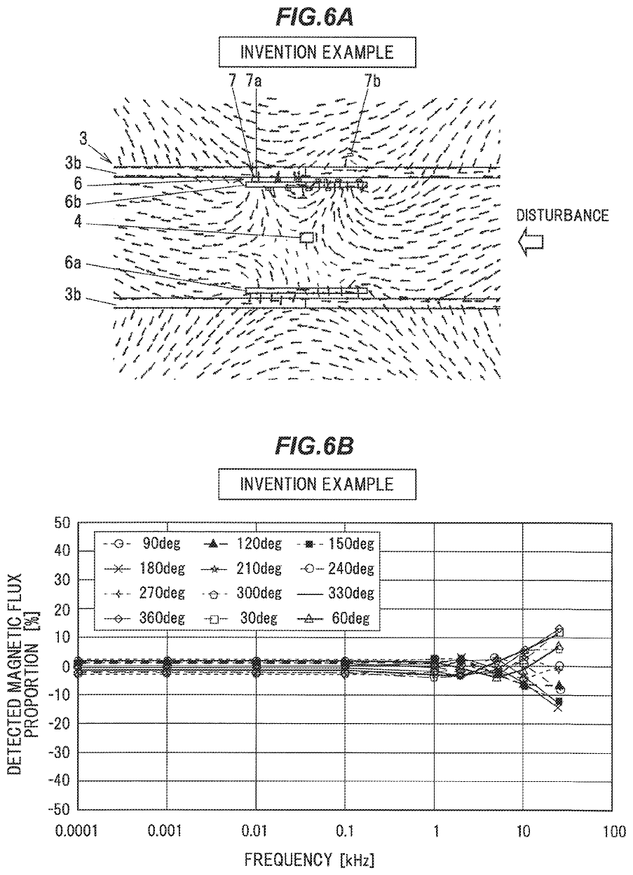

For a conventional example having no core 6 and no winding 7, a comparative example having only the cores 6, and an invention example of the present invention described in FIGS. 1A to 3, simulations were conducted to obtain magnetic field vector diagrams for magnetic fields resulting from a disturbance, and detected magnetic flux proportions for magnetic fluxes resulting from the disturbance in the magnetic detection element 4. Because the detected magnetic flux proportions varied according to disturbance generating external magnetic field phases, the simulations were performed for each disturbance generating external magnetic field phase. Herein, the detected magnetic flux proportion was defined as the proportion of the magnetic flux density detected in the magnetic detection element 4 resulting from the disturbance, to the magnetic flux density detected in the magnetic detection element 4 resulting from electric current flowing in the bus bar 2. Simulation results on the conventional example are shown in FIGS. 4A and 4B, and simulation results on the comparative example are shown in FIGS. 5A and 5B, while simulation results on the invention example are shown in FIGS. 6A and 6B.

FIG. 4A shows a magnetic flux density vector diagram at 10 kHz in the case of the conventional example (with no core 6 and no winding 7). As shown in FIG. 4B, in the conventional example, especially at frequencies of the disturbance generating external magnetic field of 1 kHz or higher, the detected magnetic flux proportion of the magnetic flux resulting from the disturbance was high, leading to a lowering in detection accuracy in the magnetic detection element 4. Note that although the cores 6 and the winding 7 are shown in FIG. 4A for reference, the cores 6 and the winding 7 were simulated as air in the simulation.

As shown in FIG. 5A, in the comparative example, by providing the cores 6, the disturbance was suppressed in the location of the magnetic detection element 4. For that reason, as shown in FIG. 5B, in the comparative example, in frequency regions of the disturbance generating external magnetic field of 1 kHz or higher, the detected magnetic flux proportion of the magnetic flux resulting from the disturbance was slightly lowered, as compared with the conventional example. Note that although the winding 7 is shown in FIG. 5A for reference, the winding 7 was simulated as air in the simulation.

On the other hand, as shown in FIG. 6A, in the invention example according to the present invention, the disturbance was greatly suppressed in the location of the magnetic detection element 4 by the creation of the induction magnetic field in the core 6. For this reason, as shown in FIG. 6B, especially in frequency regions of the disturbance generating external magnetic field of 1 kHz or higher, the detected magnetic flux proportion of the magnetic flux resulting from the disturbance was low, as compared with the conventional example and the comparative example.

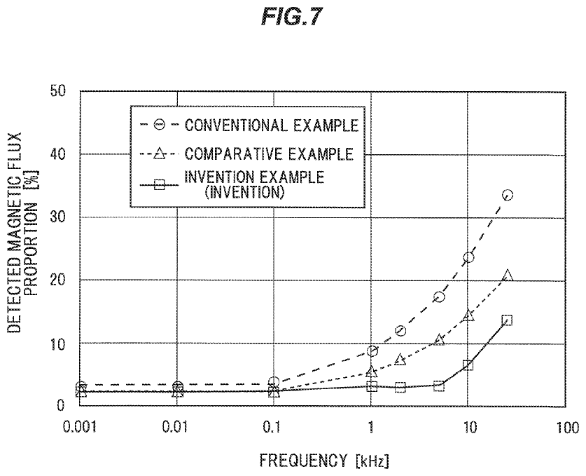

In FIG. 7, graphs are shown in which maximal values of the detected magnetic flux proportions (values of the highest detected magnetic flux proportions in all the phases) at each frequency in FIGS. 4B, 5B, and 6B are plotted together. As shown in FIG. 7, in the invention example according to the present invention, the detected magnetic flux proportion of the magnetic flux resulting from the disturbance was greatly lowered, as compared with the conventional example and the comparative example. For example, at a frequency of the disturbance generating external magnetic field of 10 kHz, the invention example according to the present invention was able to lower the detected magnetic flux proportion of the magnetic flux resulting from the disturbance by 70% or more, as compared with the conventional example. In this manner, the electric current sensor 1 is able to suppress the influence of the disturbance caused even when a high frequency, say, 1 kHz or higher AC magnetic field is applied as the disturbance (the disturbance generating external magnetic field), and thereby makes it possible to perform a high precision electric current detection.

(Operations and Advantageous Effects of the Embodiment)

As described above, the electric current sensor 1 according to the present embodiment is configured to include the cores 6 made of the magnetic material and disposed between the one pair of shield plates 3, and the winding 7 including one part of the winding 7 being wound around the core 6 and the other part of the winding 7 being wound around the shield plate 3. By configuring the electric current sensor 1 in this manner, even when a high frequency AC magnetic field is applied as the disturbance (the disturbance generating external magnetic field), since the induction magnetic field to be created in the core 6 cancels out the disturbance generating external magnetic field in the location of the magnetic detection element 4, the electric current sensor 1 substantially unaffected by the disturbance generated by the external magnetic field can be achieved.

(Modification)

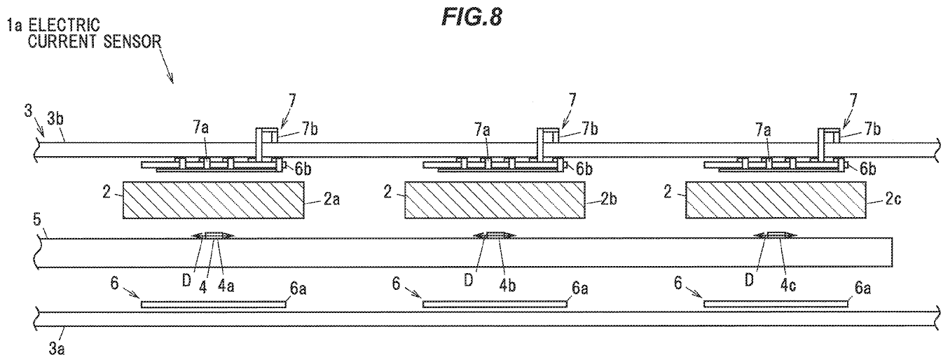

FIG. 8 shows an electric current sensor 1a, which is capable of measuring electric currents of each phase (a U phase, a V phase and a W phase) of a three-phase alternating current. This electric current sensor 1a is configured to include three bus bars 2a to 2c through which the electric currents, respectively, of each phase of the three-phase alternating current are to be passed. The three bus bars 2a to 2c are arranged side by side in the width direction, and one pair of shield plates 3a and 3b are provided in such a manner as to sandwich those three bus bars 2a to 2c together therebetween in the thickness direction. Further, magnetic detection elements 4a to 4c are provided to be oriented opposite the bus bars 2a to 2c, respectively, in the thickness direction. The magnetic detection elements 4a to 4c are mounted on a common substrate 5.

As in the electric current sensor 1a, when a plurality of the bus bars 2 are provided, it is desirable that the cores 6 and the windings 7 be separately provided in such a manner as to be associated with each of the bus bars 2. This is because it can be considered likely that, since the induction magnetic field created in the core 6 is more radiated from an end portion of the core 6 into the space, when the cores 6 of each phase are coupled and integrally configured, the disturbance may be not sufficiently canceled out in a location separate from the end portion of the cores 6 (for example, in the location of the magnetic detection element located midway). Further, separately providing the cores 6 and the windings 7 for each of the bus bars 2 makes it possible to suppress variations in the induction magnetic fields induced in the cores 6 due to the influences of the other bus bars 2, and resulting lowerings in electric current detection accuracy, and also makes it possible to suppress the interferences from the other phases.

### SUMMARY OF THE EMBODIMENTS

Next, the technical ideas grasped from the above-described embodiments will be described with the aid of the reference characters and the like in the embodiments. It should be noted, however, that each of the reference characters and the like in the following descriptions is not to be construed as limiting the constituent elements in the claims to the members and the like specifically shown in the embodiments.

[1] An electric current sensor (1), comprising:

a plate-like shape bus bar (2), through which an electric current to be detected is to be passed;

one pair of shield plates (3), which are made of a magnetic material and disposed in such a manner as to sandwich the bus bar (2) between the one pair of the shield plates (3) in a thickness direction of the bus bar (2);

a magnetic detection element (4), which is disposed between the bus bar (2) and one of the shield plates (3) to detect a strength of a magnetic field to be produced by the electric current to be passed through the bus bar (2);

a core (6), which is made of a magnetic material and disposed between the one pair of the shield plates (3); and

a winding (7), which includes one part wound around the core (6) and an other part wound around either of the shield plates (3).

[2] The electric current sensor (1) according to [1] above, further including:

two of the cores (6) formed in a plate-like shape, and disposed both between the magnetic detection element (4) and one of the shield plates (3), and between the magnetic detection element (4) and an other of the shield plates (3), respectively, with the winding (7) being provided around at least one of the two cores (6).

[3] The electric current sensor (1) according to [1] or [2] above, wherein a number of turns in the winding (7) around the core (6) is larger than a number of turns in the winding (7) around either of the shield plates (3).

[4] The electric current sensor (1) according to any one of [1] to [3] above, wherein the core (6) is disposed in such a manner that the entire core (6) is sandwiched between the one pair of the shield plates (3).

[5] The electric current sensor (1) according to any one of [1] to [4] above, wherein the core (6) is disposed in such a manner that a magnetic field to be induced in the core (6) by an induction current flowing in the winding (7) includes a direction component along a detection axis (D) of the magnetic detection element (4).

Although the embodiments of the present invention have been described above, the above described embodiments are not to be construed as limiting the inventions according to the claims. Further, it should be noted that not all the combinations of the features described in the embodiments are indispensable to the means for solving the problem of the invention.

Further, the present invention can appropriately be modified and implemented without departing from the spirit thereof. For example, although in the above described embodiments, the core 6 (the core 6 with the winding 7 being wound therearound) is arranged in such a location as to overlap the magnetic detection element 4 in the thickness direction, the location to be provided with the core 6 is not limited thereto. For example, it is also possible to arrange the core 6 (the core 6 with the winding 7 being wound therearound) in such a manner as to be located adjacent to the magnetic detection element 4 in the width direction.

Although the invention has been described with respect to the specific embodiments for complete and clear disclosure, the appended claims are not to be thus limited but are to be construed as embodying all modifications and alternative constructions that may occur to one skilled in the art which fairly lowering within the basic teaching herein set forth.

What is claimed is:

1. An electric current sensor, comprising:
a plate-like shape bus bar, through which an electric current to be detected is to be passed;
one pair of shield plates, which are made of a magnetic material and disposed in such a manner as to sandwich the bus bar between the one pair of the shield plates in a thickness direction of the bus bar;
a magnetic detection element, which is disposed between the bus bar and one of the shield plates to detect a strength of a magnetic field to be produced by the electric current to be passed through the bus bar;
a core, which is made of a magnetic material and disposed between the one pair of the shield plates; and
a winding, which includes one part wound around the core, and an other part wound around either of the shield plates.

2. The electric current sensor according to claim 1, further comprising:
two of the cores formed in a plate-like shape, and disposed both between the magnetic detection element and one of the shield plates, and between the magnetic detection element and an other of the shield plates, respectively, with the winding being provided around at least one of the two cores.

3. The electric current sensor according to claim 1, wherein a number of turns in the winding around the core is larger than a number of turns in the winding around either of the shield plates.

4. The electric current sensor according to claim 1, wherein the core is disposed in such a manner that the entire core is sandwiched between the one pair of the shield plates.

5. The electric current sensor according to claim 1, wherein the core is disposed in such a manner that a magnetic field to be induced in the core by an induction current flowing in the winding includes a direction component along a detection axis of the magnetic detection element.
